(19) United States
(12) Patent Application Publication
(10) Pub. No.: US 2023/0124071 A1
(43) Pub. Date: Apr. 20, 2023

(54) PASSIVELY Q-SWITCHED LASER WITH VARIABLE OUTPUT PULSE ENERGY

(71) Applicants: Thomas James Kane, Menlo Park, CA (US); John Lawrence Nightingale, Portola Valley, CA (US)

(72) Inventors: Thomas James Kane, Menlo Park, CA (US); John Lawrence Nightingale, Portola Valley, CA (US)

(21) Appl. No.: 17/965,983

(22) Filed: Oct. 14, 2022

Related U.S. Application Data
(60) Provisional application No. 63/256,678, filed on Oct. 18, 2021.

(51) Int. Cl. H01S 3/113; H01S 3/06

(52) U.S. Cl. CPC H01S 3/113; H01S 3/0627

(57) ABSTRACT

A passively Q-switched laser with adjustable pulse parameters and a method of controlling the pulse parameters is described. The laser has a pumped spot size in a gain element that may be adjusted to control the pulse energy. The laser has a laser resonator that may have a variable resonator length to control the pulse duration.

### CROSS REFERENCE TO RELATED APPLICATIONS

This application claims priority to U.S. Provisional Pat. Application No. 63/256,678, entitled “PASSIVELY Q-SWITCHED LASER WITH VARIABLE PULSE ENERGY,” filed Oct. 18, 2021 which is incorporated herein in its entirety for all purposes.

### FIELD OF THE INVENTION

The present invention relates to systems and methods for varying the output pulse parameters in a passively Q-switched laser.

### BACKGROUND

Passively Q-switched lasers utilize a saturable absorber in a laser cavity to generate Q-switched pulses. Switching occurs when gain in a gain element is sufficient to overcome a small-signal loss in the saturable absorber element. The saturable absorber is then bleached and the stored energy in the gain element is emitted as a laser pulse. An advantage of passively Q-switched lasers is their simplicity, since no high-speed electronics are required to generate laser pulses with pulse energies exceeding 1 kW.

A passively Q-switched laser resonator may be formed by integrating resonator mirrors on the end faces of the gain element and the saturable absorber element. A high reflecting mirror may be placed on an outer surface of the gain medium and the output coupling reflector on an outer surface of the saturable absorber. The laser resonator may be end-pumped by a semiconductor laser. A pump beam emitted by the semiconductor laser is transmitted through the high reflecting mirror into the gain element, where it is absorbed. A focusing lens is typically placed between the laser resonator and the pump source to control a pump beam size in the gain element. Laser resonator stability may be obtained by thermal lensing in the gain element and/or deformation of the resonator end faces to form a stable laser cavity.

The arrangement described above is a known simple and low-cost method for generating optical pulses with high peak power. Pulse repetition rate may be varied by varying the pump power; however, the pulse energy and pulse width are substantially independent of pump power. While constant pulse energy and pulse width operation is acceptable in some applications, other applications may benefit from a laser with an adjustable pulse energy and pulse width.

What is needed is a simple system and method to vary the pulse energy and/or pulse width of a passively Q-switched laser.

### SUMMARY

In one embodiment, a passively Q-switched laser having a laser resonator is described. The laser resonator includes a gain element with a first and a second surface and a saturable absorber with a first and second surface. A first end of the laser resonator is formed by a highly reflective coating at a lasing wavelength on the first surface of the gain element. A second end of the laser resonator is formed by a partially transmitting optical coating on the second surface of the saturable absorber. A pump source emits a pump beam that is directed into the gain element forming a pumped spot. An output pulse energy of the laser is adjusted by adjusting a size of the pumped spot. The laser may be used in a laser ranging system.

In another embodiment, a method of controlling the output pulse energy of a passively Q-switched laser is described. The method includes directing a pump beam from a pump source into a pumped spot of a gain element. A size of the pumped spot is adjusted to control an output pulse energy of an emitted output pulse.

### BRIEF DESCRIPTION OF THE DRAWINGS

The invention and the advantages thereof, may best be understood by reference to the following description taken in conjunction with the accompanying drawings in which:

FIG. 1 is a schematic cross-sectional diagram of a prior art, passively Q-switched laser.

FIG. 2 is a schematic cross-sectional diagram of a passively Q-switched laser having a focusing element with an adjustable position according to an embodiment of the present invention.

FIG. 3 is a schematic cross-sectional diagram of a passively Q-switched laser having a focusing element with a reflector having an adjustable position according to an embodiment of the present invention.

FIG. 4 is a schematic cross-sectional diagram of a passively Q-switched laser having a laser resonator with an adjustable position according to an embodiment of the present invention.

FIG. 5 is a schematic cross-sectional diagram of a passively Q-switched laser having a focusing lens, a gain element, and a saturable absorber element with an adjustable position according to an embodiment of the present invention.

In the drawings, like reference numerals are sometimes used to designate like structural elements. It should also be appreciated that the depictions in the figures are diagrammatic and not to scale.

### DETAILED DESCRIPTION

The present invention relates to methods and systems for obtaining variable pulse characteristics, such as pulse energy and pulse width, from a passively Q-switched laser. One particularly attractive application for the laser is laser ranging, commonly known as LIDAR. In this application, the laser may be a passively Q-switched laser operating at an eye-safe wavelength between 1.2 and 1.4 microns. Inclusion of a saturable absorber material within the laser cavity causes the laser to passively Q-switch, resulting in a pulsed output with high peak powers, which is useful in time-of-flight ranging applications. The saturable absorber may be based on vanadium ions in a crystalline or glass host material. The gain material may be neodymium ions doped in a ceramic, crystalline or glass matrix.

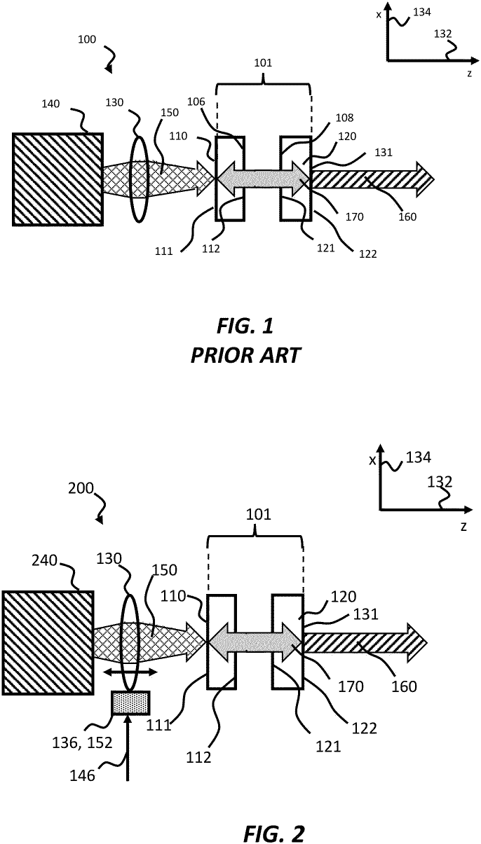

FIG. 1 depicts a cross-section of a prior art laser 100. There are two elements that form a laser resonator 101, a gain element 110 and a saturable absorber element 120. Optical coatings are applied to optically polished surfaces of the gain element 110. A first surface 111, which forms one end of the laser resonator, is coated for high transmission at a pump wavelength, and for high reflection at a lasing wavelength. A second surface 112, opposing the first surface 111, is coated for high transmission at the laser wavelength. A partially transmitting optical coating is applied to a second surface 122 of the saturable absorber element 120 to form an output coupler 131 that serves as an end mirror for the resonator 101. The first surface 121 of the saturable absorber element is anti-reflection coated at the laser wavelength. All the optical surfaces 111, 112, 121, and 122 may be flat, that is they may have no deliberately fabricated curvature. Curvature of one or more of these surfaces may be induced by application of an optical coating to the surface or by thermal effects when the resonator 101 is energized by a pump beam 150 generated by a pump laser 140. All other surfaces of the gain element 110 and saturable absorber element 120 may be non-optical surfaces, which are not arranged to transmit light. These non-optical surfaces may also be flat, but they do not need to be optically polished. One or more focusing elements 130 may be arranged to focus light from the pump laser 140 into the gain element 110. The focusing element 130 may be a single focusing lens, a plurality of lenses, or a combination of lenses and reflectors. FIG. 1 shows the focusing element being a single focusing lens. An x-direction 134 is perpendicular to a longitudinal, z- or lasing direction 132.

Both the gain element 110 and the saturable absorber element 120 are shaped as a rectangular parallelopiped. The gain element is a neodymium doped YVO₄ crystal and the saturable absorber element is a vanadium doped yttrium aluminum garnet (YAG) crystal. The lasing wavelength is approximately 1.3 microns. The gain element 110 and saturable absorber element 120 must be aligned so that resonant light 170 reflects off the two end mirror coatings and returns to the same point. The desired condition of a ray reflecting back on itself indefinitely is achieved by adjusting the alignment of the gain element 110 to the saturable absorber element 120 to angularly align the second surface 122 of the saturable absorber element with the first surface 111 of the gain element 110.

When the intensity of the pump light 150 is sufficient so that the gain element 110 has sufficient gain to overcome any losses within the laser resonator 101, the laser 100 will lase. Resonant light 170 will circulate between the first surface 111 of the gain element 110 and the second surface 122 of the saturable absorber 120. A fraction of the resonant light 170 will emerge through the output coupling reflector 131 to form the output beam 160. The optical coatings are arranged so that the output beam is at a laser wavelength of approximately 1.34 microns.

In operation, the laser 100 produces output pulses with a substantially constant pulse energy and pulse width. The pulse repetition rate may be varied by adjusting the pump power. In some applications having a substantially constant output pulse may be acceptable; however, there are applications where it would be desirable to adjust the output pulse parameters.

An improved laser that allows for an adjustable pulse energy is shown in FIG. 2, which shows a cross-sectional view in a x-z plane of a passively Q-switched laser 200 according to an embodiment of the current invention. The laser is similar to the prior art laser depicted in FIG. 1 and for brevity a description of some of the common elements will not be repeated here. The gain element 110 may have a highly reflective coating, for example, greater than approximately 95%, 98% or 99%, at a lasing wavelength on the first surface 111 of the gain element 110. The first surface 111 of the gain element 110 may form a first end of the resonator 101. The second surface 122 of the saturable absorber element 120 may have a partially transmitting coating at the lasing wavelength, for example a transmission in a range between approximately 3% and 50%. The second surface 122 may serve as an output coupler 131 and may form a second end of the resonator 101. Unlike the prior art laser 100 depicted in FIG. 1, the passively Q-switched laser 200 has an adjustable pumped spot size in the gain element. The pumped spot size may be adjusted by controlling the position of the focusing element 130 along the z- or lasing direction 132. As in the prior art, all the optical surfaces 111, 112, 121, and 122 may be flat, that is they may have no deliberately fabricated curvature. In some embodiments, one or more of the optical surfaces 111, 112, 121, and 122 may have a deliberately fabricated curvature to enhance transverse mode control. A pump source 240 is preferably a pump laser, similar to that used in the prior art, or it may be a light emitting diode.

The focusing element 130 may be mounted to an actuator, which allows control of the focusing element position in response to application of a control signal. For example, the actuator may be a focusing lens mount 136 that can move along the z-direction 132 in response to a control signal 146. The control signal 146 may be an analog signal that varies the position of the focusing element 130 in an analog manner. Alternatively, the control signal 146 may be a digital or multi-level digital signal wherein the position of the focusing element 130 is varied between several predetermined positions, such as two, three, four, or more positions. Each predetermined position has as associated pumped spot size such that there are a plurality of predetermined pumped spot sizes.

The focusing lens mount 136 may be part of or mechanically attached to a plunger of a solenoid or may be part of a voice coil. The control signal 146 may be a current applied to coils of the solenoid or voice coil that will cause the plunger/voice coil, and thus the focusing element 130, to move. Alternatively, the focusing lens mount 136 may be a MEMS (micro-electromechanical system) device with an armature that moves in response to the control signal 146. Other types of mechanical actuators may be used to adjust the position of the focusing element 130.

Assuming a constant pump power, increasing the size of the pumped spot will decrease the single pass gain in the gain element 110, since the same pump energy is spread over a larger area. Thus, more energy must be deposited into the gain element 110 to overcome the small signal loss of the saturable absorber element 120 to initiate lasing. The resultant output pulses will thus have a higher pulse energy, but will be less frequent, i.e., the pulse frequency will be lower. Similarly decreasing the pumped spot size will decrease the output pulse energy and increase the pulse frequency. The pump power may be adjusted in concert with adjustment of the pumped spot size. If a constant pulse frequency is required, the pump power may be adjusted to maintain a constant pulse frequency over a range of different pumped spot sizes. In some embodiments, the pump power may be adjusted or modulated to obtain a desired pulse frequency.

The pump source 240 may be a broad area, edge-emitting semiconductor laser, often referred to as a laser diode. The laser diode is formed from a plurality of epitaxial layers deposited on a planar semiconductor substrate. The emission pattern of the laser diode is asymmetric, with a high divergence emission pattern in a plane perpendicular to the planar semiconductor substrate and a low divergence emission pattern in a plane parallel to the planar semiconductor substrate. As such, the cross-sectional shape of the emission pattern varies along a propagation path of the pump beam 150. The focusing element 130 may be an anamorphic lens having a different optical power in the low- and high-divergence directions. Use of an anamorphic lens may allow the pumped spot to be substantially symmetric for at least one focusing element 130 position. It should be understood that the laser 200 need not have a symmetric pumped spot to operate, but it may be advantageous for the degree of asymmetry to be small, for example, the spot size in the low and high divergence directions may be within 50% of each other.

Laser resonator stability may be obtained by thermal lensing in the gain element and/or deformation of the resonator end faces to form a stable laser cavity. The passively Q-switched laser 200 may operate on a single transverse mode. The output beam 160 may thus have an M² value of less than approximately 1.5. The passively Q-switched laser 200 may operate on a single longitudinal mode or may operate on multiple longitudinal modes. The longitudinal mode distribution may vary on a pulse-to-pulse basis.

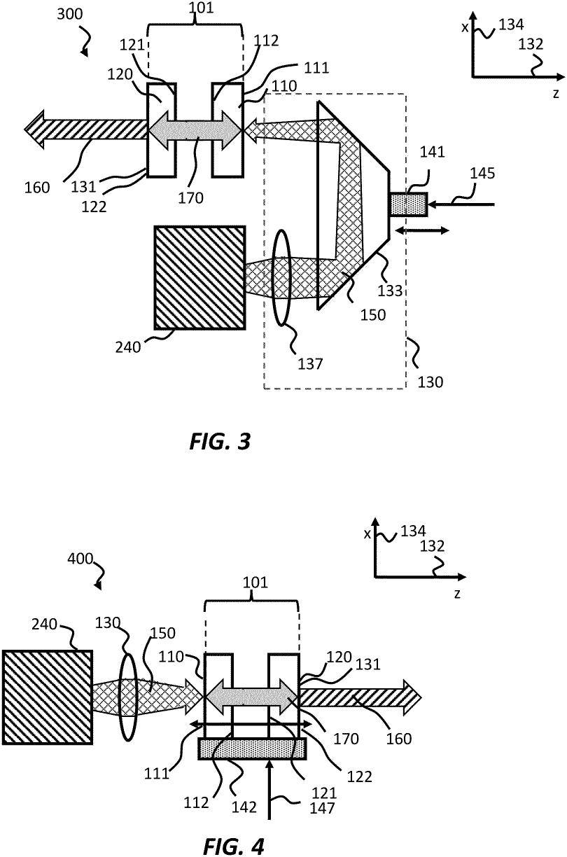

FIG. 3 shows a schematic cross-sectional diagram of a passively Q-switched laser 300 having a focusing element 130 with a retroreflector 133 having an adjustable position according to an embodiment of the present invention. The laser is similar to the prior art laser depicted in FIG. 2 and for brevity a description of some of the common elements will not be repeated here. In this embodiment, the focusing element 130 consists of a focusing lens 137 and the retroreflector 133. Application of a control signal 145 to a reflector mount 141 may cause the retroreflector 133 to move along the z-direction 132. This motion changes an optical path length of the pump beam 150 between the pump source 240 and resonator 101 changing the size of a pumped spot in the gain element 110. In an alternative embodiment, the focusing lens 137 may be integrated into the retroreflector 133 so that they move as a unit.

In an alternative embodiment an optical fiber may be used between the pump source 240 and focusing element 130. Use of an optical fiber both symmetrizes the pump beam 150 and allows the pump source 240 to be positioned remotely from the laser resonator 101.

As described above, only the focusing element 130 has an adjustable position, but the invention is not so limited. In other embodiments, the gain element 110 or the saturable absorber element 120 may have an adjustable position. In some embodiments, two elements, such as the gain element 110 and the saturable absorber element 120, may move in tandem. FIG. 4 shows a passively Q-switched laser 400 with the gain element 110 and the saturable absorber element 120 mounted to a resonator mount 142 that moves in response to a control signal 147 such that a distance between the resonator 101 and the pump source 240 may be adjusted.

In other embodiments, rather than the entire focusing element 130 shifting to a new position, various components internal to the focusing element 130 may shift their position to change an optical power of the focusing element and thereby adjust a size of a pumped spot.

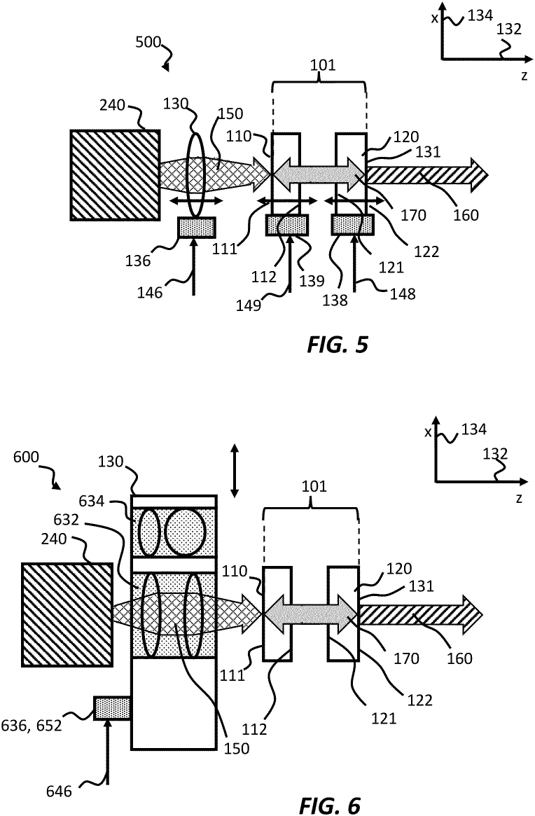

FIG. 5 shows another passively Q-switched laser 500 according to an embodiment of the current invention. The passively Q-switched laser 500 is similar to the previously described passively Q-switched lasers 200, 300, and 400 and for brevity a description of the common elements will not be repeated here. A difference between passively Q-switched laser 500 and the previously disclosed lasers is that the focusing lens 130, the gain element 110, and the saturable absorber element 120 are all capable of motion. The gain element 110 may be mounted to a gain element mount 139 that can move along the z-direction in response to a control signal 149. Likewise, the saturable absorber element 120 may be mounted to a saturable absorber mount 138 that can move along the z-direction in response to a control signal 148. Such an arrangement allows both the pumped spot size and resonator length to be varied. Adjustment of the resonator length allows control of the pulse width, with longer resonators having larger pulse widths. If the resonator length is changed while maintaining a constant pump spot size, the pulse energy may remain substantially constant while the pulse width is varied.

In yet another embodiment, the focusing element 130 may be eliminated. This arrangement may be referred to as butt-coupling since the pump source 240 is directly butted adjacent the laser resonator 101. In this case, the size of the pumped region may be varied by changing the distance between the pump source 240 and resonator 101.

In yet another alternative embodiment, the size of the pumped spot may be adjusted by controlling an optical power of the focusing element 130. The optical power may be changed by changing the curvature of an optical surface in the focusing element 130. The focusing element 130 may consist of a plurality of individual lenses arranged to yield a desired pumped spot size in the gain element 110. Adjusting an internal position of various elements in a multi-element focusing lens may control the optical power of the focusing element 130. In embodiments where the optical power of the focusing element 130 is adjustable, the position of the focusing element 130 and laser resonator 101 may remain fixed.

FIG. 6 shows another embodiment of a passively Q-switched laser 600 configured to have adjustable output pulse characteristics. The passively Q-switched laser 600 is similar to the previously described passively Q-switched lasers 200, 300, 400, and 500 and for brevity a description of the common elements will not be repeated here. A difference between the passively Q-switched laser 600 and the previously described Q-switched lasers 200, 300, 400, and 500 is a direction of motion of a laser element that enables adjustable output pulse characteristics. In the previously disclosed embodiments, one or more laser elements moved in the longitudinal, lasing or z-direction 132. In the embodiment depicted in FIG. 6, the focusing element 130 moves in the x direction 134, which is orthogonal to the z-direction 132. By shifting the position of the focusing element 130 in the x-direction 134, one of a plurality of focusing assemblies 632 and 634 may be placed in the pump beam 150. In FIG. 6 focusing assembly 632 is depicted as being in the pump beam 150. The focusing assemblies 632 and 634 may have different optical properties, so that a size of a pumped spot in the gain element 110 may be adjusted.

Position of the focusing element 130 and thus the focusing assemblies 632 and 634 may be controlled by an actuator 652. The actuator 652 may be responsive to a control signal 646, which directs the focusing element 130 to move so as to align either of the focusing assemblies 632 or 634 with the pump beam 150. The actuator 652 may be a focusing element mount 636 which is configured to move the focusing element 130 in the x-direction.

It should be appreciated that while two focusing assemblies 632 and 634 are shown in FIG. 6, the invention is not so limited. Any number of focusing assemblies, such as 3, 4, or more focusing assemblies, may be arranged in the focusing element 130. The focusing assemblies need not be arranged in a linear manner but may be arranged in a circular configuration. The actuator 652 may then be a rotary motor that rotates the focusing element 130 into the correct rotational alignment so that one of the focusing assemblies is aligned with the pump beam 150.

Both the focusing assemblies 632 and 634 in FIG. 6 are depicted as consisting of two lenses. This is not a requirement, as any number of lenses may be used in a focusing assembly.

Any of the laser systems and control methods described herein may be used in a laser ranging system. The ranging system may include the laser and a photodetector responsive to the emitted laser wavelength. A control unit may measure an elapsed time between emission of an output pulse and detection of the output pulse reflected from a target to determine a distance between the laser ranging system and the target.

As disclosed above, the optically pumped gain element may be composed of a gain material having neodymium ions doped in a ceramic, crystalline or glass matrix. The neodymium ions have multiple possible laser transitions. There may be a low gain laser transition and a high gain laser transition. In particular, there are laser transitions that emit light at wavelengths of 1061 and 1064 nm and 1319 and 1338 nm. The wavelengths near 1.06 microns may be characterized as corresponding to high gain laser transitions and the wavelengths near 1.3 microns may be characterized as corresponding to low gain laser transitions. The transitions emitting light near 1.3 microns produce light at an eye-safe wavelength, whereas the transitions emitting light near 1.06 microns do not. The transitions near 1.06 microns have higher gain than those near 1.3 microns. If eye-safe operation of the passively Q-switched laser is desired, a Q-switched lasing wavelength must be generated by the low gain laser transition. This requires the Q-switch laser resonator being arranged to suppress lasing near 1.06 microns. To suppress 1.06 micron lasing, the resonator must have higher losses for wavelengths near 1.06 microns as compared to 1.3 microns. Higher losses at 1.06 microns may be achieved in a number of ways including, but not limited to, coating the resonator end mirrors so they have lower reflectivity at 1.06 microns than 1.3 microns or adding an intracavity wavelength filter to absorb or deflect outside of the resonator 1.06 micron light. Also, refraction at an obliquely angled surface can result in the resonator being aligned for the low gain laser transition and not aligned for the high gain laser transition. This arrangement dramatically increases the losses for the high gain laser transition promoting lasing on the low gain laser transition.

Although only a few embodiments of the invention have been described in detail, it should be appreciated that the invention may be implemented in many other forms without departing from the spirit or scope of the invention. The invention has been described primarily as a passively Q-switched laser that may be applied to laser ranging applications, but the invention is not so limited. The laser and control methods described herein may be used in other applications requiring a Q-switched output. For example, the laser may be used in spectroscopic or material processing applications The laser wavelength is not limited to 1.3 microns but may be between approximately 0.9 to 2.2 microns by using different materials for the gain element and the saturable absorber. For example, the gain element may be Nd:YAG, which can lase at a wavelength of either approximately 1.06 or 1.3 microns and can be passively Q-switched with Cr:YAG at 1.06 microns or V:YAG at 1.3 microns. In other embodiments, the relative distance between the pump source and other laser elements may be varied by moving the pump source with the other laser elements laser remaining fixed. The invention has generally been described as having a separate gain element and saturable absorber element with a gap between them; however, in some embodiments the gain element and saturable absorber element may form a monolithic, unitary structure. In embodiments having a gap between the gain element and saturable absorber element an aperture or opaque edge may be placed in the gap to suppress operation on higher order transverse modes and encourage single transverse mode operation. Therefore, the present embodiments should be considered illustrative and not restrictive, and the invention is not to be limited to the details given herein.

What is claimed is:

1. A passively Q-switched laser having a laser resonator comprising:
a gain element having a first and a second surface,
a first end of the laser resonator formed by a highly reflective coating at a lasing wavelength on the first surface of the gain element;
a saturable absorber element having a first and second surface;
a second end of the laser resonator formed by a partially transmitting optical coating on the second surface of the saturable absorber element; and
a pump source that emits a pump beam that is directed into the gain element forming a pumped spot in the gain element, wherein an output pulse energy of the laser is adjusted by adjusting a size of the pumped spot.

2. The laser as recited in claim 1, further comprising a control signal that controls the size of the pumped spot.

3. The laser as recited in claim 1, further comprising a focusing element positioned between the pump source and the laser resonator, wherein the focusing element focuses the pump beam to form the pumped spot in the gain element.

4. The laser as recited in claim 3, wherein the size of the pumped spot is adjusted by controlling a position of the focusing element.

5. The laser as recited in claim 3, wherein the size of the pumped spot is adjusted by controlling an optical power of the focusing element.

6. The laser as recited in claim 3, wherein the focusing element is an anamorphic lens.

7. The laser as recited in claim 3, wherein the focusing element includes a retroreflecting mirror.

8. The laser as recited in claim 3, further comprising an optical fiber positioned between the pump source and the focusing element.

9. The laser as recited in claim 1, wherein the size of the pumped spot is selected from a plurality of predetermined pumped spot sizes.

10. The laser as recited in claim 1, wherein the size of the pumped spot is continuously adjustable.

11. The laser as recited in claim 1, wherein the size of the pumped spot is adjusted by controlling a distance between the laser resonator and the pump source.

12. The laser as recited in claim 1, wherein the laser resonator is butt coupled to the pump source.

13. The laser as recited in claim 1, wherein a length of the laser resonator is adjusted to control an output pulse duration.

14. A laser ranging system comprising:
the passively Q-switched laser as recited in claim 1;
a photodetector; and
a control unit that measures an elapsed time between emission of an output pulse and detection of the output pulse reflected from a target to determine a distance between the laser ranging system and the target.

15. A method of controlling a passively Q-switched laser comprising:
directing a pump beam from a pump source into a pumped spot of a gain element; and
adjusting a size of the pumped spot to control an output pulse energy of an emitted output pulse, wherein the size of the pump spot is adjusted by application of a control signal to an actuator.

16. The method as recited in claim 15, wherein a position of a focusing element situated between the pump source and the gain element is adjusted to control the output pulse energy.

17. The method as recited in claim 15, wherein a position of the gain element is adjusted to control the output pulse energy.

18. The method as recited in claim 15, wherein the pump beam has a pump beam power and the pump beam power is adjusted to control a pulse frequency of the emitted output pulses.

19. The method as recited in claims 18, wherein the pump beam power is adjusted to maintain a constant pulse frequency as the output pulse energy is varied.

20. A method of determining a distance to a target comprising;
the method as recited in claim 15;
detecting a reflection from a target of the output pulse; and
measuring an elapsed time between emission of the emitted output pulse and detection of the reflection of the output pulse to determine the distance to the target.
